(19) United States
(12) Patent Application Publication
(10) Pub. No.: US 2024/0244719 A1
(43) Pub. Date: Jul. 18, 2024

(54) CERAMIC HEATER AND HOLDING MEMBER

(71) Applicant: NITERRA CO., LTD, Nagoya-shi, Aichi (JP)

(72) Inventor: Keisuke SUZUKI, Nagoya-shi, Aichi (JP)

(73) Assignee: NITERRA CO., LTD, Nagoya-shi, Aichi (JP)

(21) Appl. No.: 18/289,478

(22) PCT Filed: May 16, 2022
(86) PCT No.: PCT/JP2022/020342

§ 371 Date: Nov. 3, 2023

(30) Foreign Application Priority Data
Jun. 17, 2021 (JP) 2021-100825

(51) Int. Cl. H05B 3/28; H05B 3/06

(52) U.S. Cl. CPC H05B 3/283; H05B 3/06; H05B 2203/002; H05B 2203/016

(57) ABSTRACT

This heat generating element of a ceramic heater, if viewed from the thickness direction of the ceramic heater, comprises: as a pair of heat generating lines formed from two heat generating lines adjacent to each other of the heat generating element in the radial direction, a pair of first heat generating lines and a pair of a second heat generating lines disposed apart from each other by sandwiching a prescribed separation region therebetween in the circumferential direction of the heating element; a first folded back portion connecting both ends on the separation region side of two of the heat generating lines forming the pair of first heat generating lines; and a second folded back portion connecting both ends on the separation region side of two of the heat generating lines forming the pair of second heat generating lines. At a pair of folded back portions formed from the first folded back portion and the second folded back portion, the spacing of the pair of folded back portions between the first folded back portion and the second folded back portion at the end on one side of the beat generating element in the radial direction is narrower than the spacing of the pair of folded back portions between the first folded back portion and the second folded back portion in the center of the heat generating element in the radial direction.

### TECHNICAL FIELD

The present disclosure relates to a ceramic heater, and a holding member for holding an object.

### BACKGROUND ART

As a document relating to a ceramic heater and a holding member, Patent Document 1 discloses a wafer heating device used in film formation equipment and etching equipment in manufacturing a semiconductor apparatus. In the wafer heating device disclosed in Patent Document 1, a heater pattern for heating a wafer is embedded in a ceramic substrate having a wafer support surface.

### RELATED ART DOCUMENTS

### Patent Documents

Patent Document 1: JP-B-3477062

### SUMMARY OF INVENTION

### Problems to be Solved by the Invention

In the wafer heating device disclosed in Patent Document 1, on the wafer support face of the ceramic substrate, folded-back portions in the heater pattern are brought close to each other in a position where the heater pattern is folded back, and thus, a distance between the centers of the folded-back portions is short, thereby generating a hot spot. In addition, in a position on an outermost circumferential portion on an outer circumferential side with respect to a position corresponding to the outermost circumference of the heater pattern, no heater pattern is embedded, and thus temperature tends to decrease, thereby generating a cold spot. Thus, on the wafer support face of the ceramic substrate, the position on the outermost circumferential portion becomes a temperature singular point, thereby causing reduction in thermal uniformity.

The present disclosure has been made to solve the above problem, and an object thereof is to provide a ceramic heater capable of improving thermal uniformity of a surface and a holding member having the ceramic heater.

### Means of Solving the Problems

An aspect of the present disclosure made to solve the above problem is directed to a ceramic heater having a plate shape, the ceramic heater including: a ceramic substrate; and a heat generating element that is embedded in the ceramic substrate and in which linear heat generating lines are arranged substantially concentrically. When seen in a thickness direction of the ceramic heater, the heat generating element includes: a pair of heat generating lines that are formed by two of the heat generating lines adjacent to each other in a radial direction of the heat generating element, the pair of heat generating lines including a first heat generating line pair and a second heat generating line pair that are arranged apart from each other with a predetermined separation region therebetween in a circumferential direction of the heat generating element; a first folded-back portion that connects ends, on the separation region side, of the two heat generating lines forming the first heat generating line pair; and a second folded-back portion that connects ends, on the separation region side, of the two heat generating lines forming the second heat generating line pair. A pair of folded-back portions formed by the first folded-back portion and the second folded-back portion is arranged such that an interval between the first folded-back portion and the second folded-back portion at ends of the pair of folded-back portions on one side in the radial direction of the heat generating element is narrower than an interval between the first folded-back portion and the second folded-back portion at middle portions of the pair of folded-back portions in the radial direction of the heat generating element.

According to this aspect, the interval between the pair of folded-back portions is narrower at the ends on the one side in the radial direction, and thus a heat quantity can be increased around the ends on the one side in the radial direction. Thus, generation of a cold spot can be prevented in a portion around the ends on the one side in the radial direction where temperature tends to decrease. In addition, the interval between the folded-back portions in pair is wide between the middle portions in the radial direction, and thus the heat quantity can be reduced around the middles portion in the radial direction. Thus, generation of a hot spot can be prevented in a portion around the middle portions in the radial direction where temperature tends to increase. Therefore, temperature distribution around the pair of folded-back portions, and thermal uniformity on a surface of the ceramic heater can be improved.

In the above aspect, the ends of the pair of folded-back portions, on the one side in the radial direction of the heat generating element, are ends of the pair of folded-back portions, on an outer circumferential side in the radial direction of the heat generating element, and the interval between the first folded-back portion and the second folded-back portion at the ends of the pair of folded-back portions on the outer circumferential side in the radial direction of the beat generating element is narrower than the interval between the first folded-back portion and the second folded-back portion at ends of the pair of folded-back portions on an inner circumferential side in the radial direction of the heat generating element.

According to this aspect, the interval between the pair of folded-back portions is narrower between the ends on the outer circumferential side in the radial direction, and thus the heat quantity can be increased around the ends on the outer circumferential side in the radial direction. Thus, generation of a cold spot can be prevented in a portion around the ends on the outer circumferential side in the radial direction where temperature tends to decrease, that is, a portion (specifically, a portion on the outer circumferential side in the radial direction with respect to the separation region) where no heat generating element is arranged because the heat generating element is folded back. Therefore, thermal uniformity on the surface of the heater can be improved.

Another aspect of the present disclosure made to solve the above problem is directed to a ceramic heater having a plate shape, the ceramic heater including: a ceramic substrate; and a heat generating element that is embedded in the ceramic substrate and in which linear heat generating lines are arranged substantially concentrically. When seen in a thickness direction of the ceramic heater, the heat generating element includes: a pair of heat generating lines that are formed by two of the heat generating lines adjacent to each other in a radial direction of the heat generating element, the pair of heat generating lines including a first heat generating line pair and a second heat generating line pair that are arranged apart from each other with a predetermined separation region therebetween in a circumferential direction of the heat generating element; a first folded-back portion that connects ends, on the separation region side, of the two heat generating lines forming the first heat generating line pair; and a second folded-back portion that connects ends, on the separation region side, of the two heat generating lines forming the second heat generating line pair. A pair of folded-back portions formed by the first folded-back portion and the second folded-back portion is arranged such that an interval between the first folded-back portion and the second folded-back portion at ends of the pair of folded-back portions on an outer circumferential side in the radial direction of the heat generating element is narrower than an interval between the first folded-back portion and the second folded-back portion at ends of the pair of folded-back portions on an inner circumferential side in the radial direction of the heat generating element.

According to this aspect, the interval between the pair of folded-back portions is narrower at the ends on the outer circumferential side in the radial direction, and thus a heat quantity can be increased around the ends on the outer circumferential side in the radial direction. Thus, generation of a cold spot can be prevented in a portion around the ends on the outer circumferential side in the radial direction where temperature tends to decrease, that is, a portion where no heat generating element is arranged because the heat generating element is folded back. Therefore, thermal uniformity on a surface of the heater can be improved.

In the above aspect, the interval between the first folded-back portion and the second folded-back portion preferably is narrower from between the ends on the inner circumferential side in the radial direction of the heat generating element toward between the ends on the outer circumferential side in the radial direction of the heat generating element.

According to this aspect, the heat quantity can be increased from the position of the ends of the pair of folded-back portions on the inner circumferential side in the radial direction toward the position of the ends of the pair of folded-back portions on the outer circumferential side in the radial direction. Thus, thermal uniformity on the surface of the heater can be improved more effectively.

In the above aspect, the pair of folded-back portions are preferably formed in a position on an outermost circumferential side of the heat generating element.

In a portion on an outer circumferential side in the radial direction with respect to the outermost circumferential side of the heat generating element, temperature tends to decrease because no heat generating element is arranged. In particular, in the outer circumferential-side portion in the radial direction with respect to the separation region between the pair of folded-back portions on the outermost circumferential side of the heat generating element, temperature tends to greatly decrease and a cold spot is easily generated. Accordingly, in this aspect, the heat quantity can be increased around the ends, on the outer circumferential side in the radial direction, of the pair of folded-back portions on the outermost circumferential side of the heat generating element, and thus generation of a cold spot can be prevented on the outer circumferential-side portion in the radial direction with respect to the separation region between the pair of folded-back portions on the outermost circumferential side of the heat generating element.

In the above aspect, the ceramic substrate preferably includes: a first portion having a holding surface for holding an object; and a second portion that is located on a side opposite to the holding surface of the first portion in a thickness direction of the ceramic heater, and that has an outer circumference larger than that of the first portion when seen from the thickness direction of the ceramic heater, and the heat generating element is preferably provided in the first portion.

In an outer circumferential-side portion of the second portion, which is larger than the first portion, no heat generating element is arranged, so that temperature tends to decrease and a cold spot is easily generated. Accordingly, in this aspect, the interval between the pair of folded-back portions is narrower at the position of the ends on the outer circumferential side in the radial direction, and thus the heat quantity can be increased around the ends on the outer circumferential side in the radial direction. Thus, generation of a cold spot can be prevented in a portion around the ends on the outer circumferential side in the radial direction where temperature tends to decrease, that is, a portion where no heat generating element is arranged because the heat generating element is folded back. Therefore, thermal uniformity on the surface of the heater can be improved.

If the heat generating element is provided in the second portion, there is a possibility that heat is released radially outward. However, when the heat generating element is provided in the first portion, the heat is less likely to be released to the radially outer side. Thus, the holding surface for holding an object can be heated more effectively. Therefore, generation of a cold spot can be prevented and thermal uniformity can be improved.

In the above aspect, at the position of the ends of the pair of folded-back portions, on the one side or the outer circumferential side in the radial direction of the heat generating element, at least one of: a corner part where the end on the separation region side of the heat generating lines forming the first heat generating line pair is connected with the first folded-back portion; and a corner part where the end on the separation region side of the heat generating lines forming the second heat generating line pair is connected with the second folded-back portion is preferably formed in an R shape on the inner peripheral side thereof.

According to this aspect, occurrence of a crack at the corner part of the heat generating element can be prevented.

Another aspect of the present disclosure made to solve the above problem is directed to a holding device for holding an object including the ceramic heater.

### Effects of the Invention

In a ceramic heater and a holding member of the present disclosure, thermal uniformity on a surface of a ceramic heater can be improved.

### BRIEF DESCRIPTION OF THE DRAWINGS

FIG. 1 is a schematic perspective view of an electrostatic chuck according to the present embodiment;

FIG. 2 is an XY plan view of the electrostatic chuck according to the present embodiment;

FIG. 3 is an XZ sectional view of a ceramic member according to the present embodiment;

FIG. 4 is a top view of a heat generating element according to the present embodiment;

FIG. 5 is an enlarged view of a pair of folded-back portions and the periphery thereof, positioned on an outermost circumferential side of the heat generating element according to the present embodiment;

FIG. 6 shows a modification of a pair of folded-back portions positioned on an outermost circumferential side of a heat generating element;

FIG. 7 shows a modification of a pair of folded-back portions positioned on an outermost circumferential side of a heat generating element;

FIG. 8 shows a modification of a pair of folded-back portions positioned on an outermost circumferential side of a heat generating element;

FIG. 9 is an enlarged view of a pair of folded-back portions and the periphery thereof, positioned on an outermost circumferential side of a heat generating element according to a conventional art; and

FIG. 10 shows an evaluation result of temperature distribution of a portion corresponding to a pair of folded-back portions and the periphery thereof, positioned on an outermost circumferential side of a heat generating element on a holding surface of a ceramic member in the conventional art.

### MODE FOR CARRYING OUT THE INVENTION

Embodiments of a ceramic heater and a holding member of the present disclosure will be described. The present embodiments will be described by exemplifying a ceramic member 10 as the ceramic heater, and an electrostatic chuck 1 as the holding member.

### <Overall Description of Electrostatic Chuck>

The electrostatic chuck 1 of the present embodiment is a device that attracts and holds a semiconductor wafer W with an electrostatic attraction force, and is used to fix the semiconductor wafer W inside a vacuum chamber of a semiconductor manufacturing apparatus, for example. The semiconductor wafer W is one example of an “object” of the present disclosure.

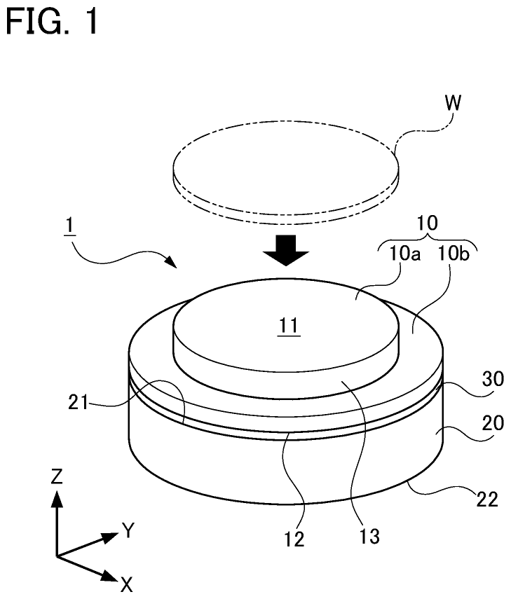

As shown in FIG. 1, the electrostatic chuck 1 has a ceramic member 10, a base member 20, and a bonding layer 30 for bonding the ceramic member 10 and the base member 20. The ceramic member 10 is one example of a “ceramic heater” or a “ceramic substrate” of the present disclosure.

In the following description, for convenience of explanation, X, Y, and Z axes are defined as shown in FIG. 1. Here, the Z axis is an axis in a direction of a central axis Ca of the electrostatic chuck 1, i.e., in an up-down direction in FIG. 1, and the X axis and the Y axis are axes in a radial direction of the electrostatic chuck 1.

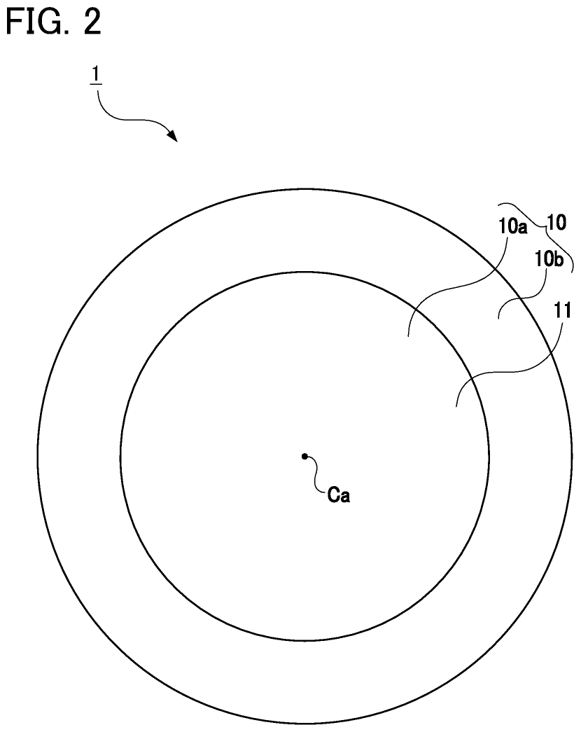

The ceramic member 10 is a plate-shaped member, specifically, a disk-shaped member as shown in FIG. 1, and is made of ceramic, i.e., formed of a ceramic substrate. In particular, the ceramic member 10 has a stepped disk shape in which two disks having different diameters are overlapped one on the other about the same central axis Ca (see FIG. 2), specifically, is configured such that a disk-shaped upper stage part 10a having a smaller diameter is overlapped on a disk-shaped lower stage part 10b having a larger diameter.

As described above, the lower stage part 10b is located on a side opposite to a holding surface 11 of the upper stage part 10a in a thickness direction of the ceramic member 10, which corresponds to a Z-axis direction, i.e., the up-down direction. The lower stage part 10b has an outer circumference larger than that of the upper stage part 10a when seen from the thickness direction of the ceramic member 10. The upper stage part 10a is one example of a “first portion” and the lower stage part 10b is one example of a “second portion”, of the present disclosure.

Although various kinds of ceramic materials can be used, ceramic containing aluminum oxide (alumina, Al₂O₃) or aluminum nitride (AlN) as a main component is preferably used in terms of strength, wear resistance, plasma resistance, and the like, for example. The main component in the present disclosure means a component having the greatest content ratio (e.g., a component having a volume content of 90 vol % or higher).

As shown in FIG. 1 to FIG. 3, the ceramic member 10 includes the holding surface 11, which is an upper surface, for holding the semiconductor wafer W and a lower surface 12 located on the side opposite to the holding surface 11 in the thickness direction of the ceramic member 10, i.e., in the Z-axis direction. In the present embodiment, the upper stage part 10a is provided with the holding surface 11. The holding surface 11 is one example of a surface of the “ceramic heater” of the present disclosure.

Regarding the diameters of the ceramic member 10, a diameter of the lower stage part 10b is larger than that of the upper stage part 10a. For example, the diameter of the upper stage part 10a is about 150 to 300 mm, and the diameter of the lower stage part 10b is about 180 to 400 mm. The thickness of the ceramic member 10 is, for example, about 2 to 6 mm. The thermal conductivity of the ceramic member 10 is preferably in a range of 10 to 50 W/mK, more preferably, 18 to 30 W/mK.

The ceramic member 10 internally includes a chuck electrode (an attraction electrode), which is not shown. When voltage is applied to the chuck electrode from a power supply source, which is not shown, an electrostatic attraction force is generated in the chuck electrode, and the semiconductor wafer W is attracted to and held on the holding surface 11 by the electrostatic attraction force.

The base member 20 is placed on the side opposite to the holding surface 11 of the ceramic member 10. The base member 20 is, for example, formed in a cylindrical shape. In addition, the base member 20 is, for example, made of metal (e.g., aluminum, aluminum alloy, or the like), but may be made of a material other than metal.

As shown in FIG. 1, the base member 20 has an upper surface 21, and a lower surface 22 located on a side opposite to the upper surface 21 in the thickness direction of the base member 20, i.e., in the Z-axis direction. The upper surface 21 of the base member 20 is thermally connected to the lower surface 12 of the ceramic member 10 through the bonding layer 30.

A diameter of the base member 20 is, for example, about 180 to 400 mm. The thickness (the dimension in the Z-axis direction) of the base member 20 is, for example, about 20 to 50 mm. The thermal conductivity of the base member 20 (assumed to be aluminum) is preferably in a range of 160 to 250 W/mK, more preferably, about 230 W/mK.

The bonding layer 30 is placed between the lower surface 12 of the ceramic member 10 and the upper surface 21 of the base member 20, and bonds the ceramic member 10 and the base member 20 such that heat can be transferred therebetween.

The bonding layer 30 is made of an adhesive material such as resin (silicone resin, acrylic resin, epoxy resin, or the like) including a filler having thermal conductivity. The thickness (the dimension in the Z-axis direction) of the bonding layer 30 is, for example, about 0.1 to 1.5 mm. The thermal conductivity of the bonding layer 30 is, for example, 1.0 W/mK. The thermal conductivity of the bonding layer 30 (assumed to be silicone resin) is preferably in a range of 0.1 to 2.0 W/mK, more preferably, 0.5 to 1.5 W/mK.

### <Regarding Beat Generating Element>

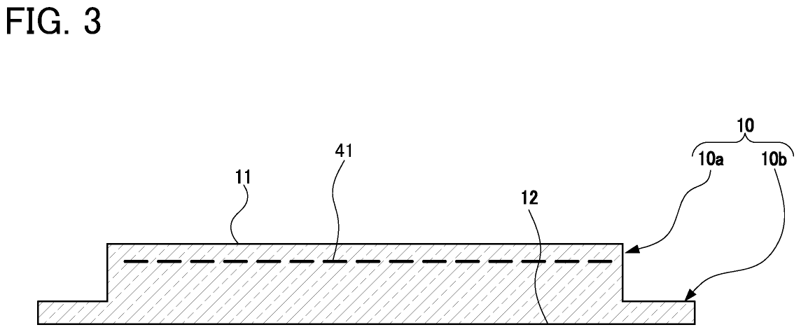

In the present embodiment, as shown in FIG. 3, the upper stage part 10a of the ceramic member 10 includes a heat generating element 41 therein. That is, the heat generating element 41 is embedded in the upper stage part 10a of the ceramic member 10. The heat generating element 41 generates heat to heat the semiconductor wafer W. The heat generating element 41 is, for example, made of tungsten, a molybdenum alloy, or the like, but may be made of another metal.

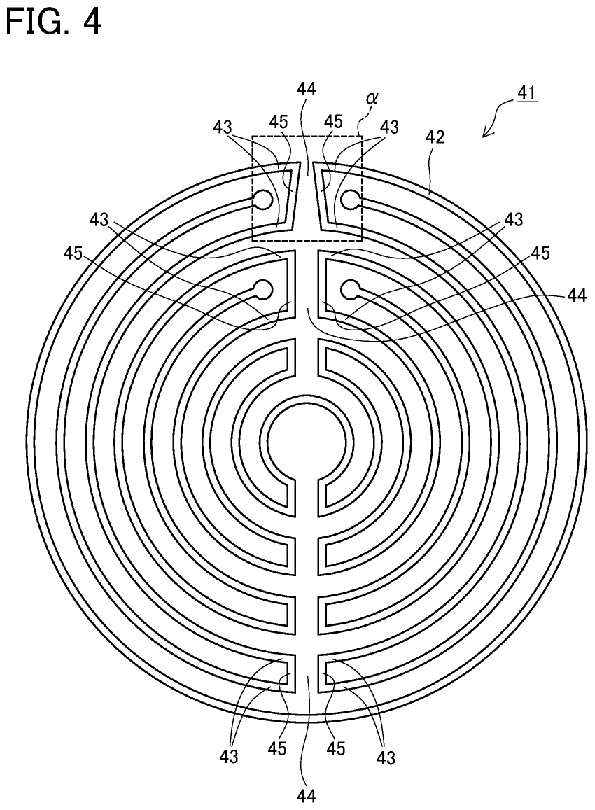

As shown in FIG. 4, the heat generating element 41 is formed such that linear heat generating lines 42 are formed substantially concentrically when seen in the thickness direction of the ceramic member 10, and a line width of each of the linear heat generating lines 42 is about 0.1 mm to 1.0 mm. The heat generating element 41 includes a pair of heat generating lines 43 formed by two heat generating lines 42 that are arranged so as to be adjacent to each other (at least partially) in a radial direction of the heat generating element 41. The two heat generating lines 42 forming the pair of heat generating lines 43 are each formed in the same circular shape. In the example shown in FIG. 4, the heat generating element 41 includes many pairs of heat generating lines 43, but only needs to include at least two pairs of heat generating lines 43.

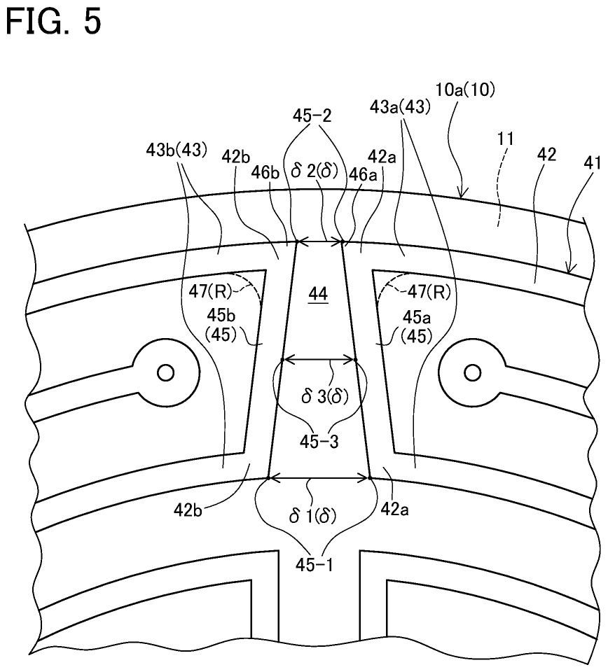

As shown in FIG. 5, the heat generating element 41 includes a first heat generating line pair 43a and a second heat generating line pair 43b, as the pairs of heat generating lines 43. The first heat generating line pair 43a and the second heat generating line pair 43b are arranged apart from each other with a predetermined separation region 44 therebetween in a circumferential direction of the heat generating element 41.

The heat generating element 41 includes a first folded-back portion 45a and a second folded-back portion 45b, as a pair of folded-back portions 45. The first folded-back portion 45a and the second folded-back portion 45b are arranged apart from each other with the predetermined separation region 44 therebetween in the circumferential direction of the heat generating element 41. The first folded-back portion 45a connects two ends 42a, on the separation region 44 side, of two heat generating lines 42 forming the first heat generating line pair 43a. The second folded-back portion 45b connects two ends 42b, on the separation region 44 side, of two heat generating lines 42 forming the second heat generating line pair 43b.

FIG. 5 shows the pair of heat generating lines 43, the separation region 44, and the pair of folded-back portions 45 positioned on an outermost circumferential side of the heat generating element 41, but the pair of heat generating lines 43, the separation region 44, and the pair of folded-back portions 45 are also similarly provided at positions other than the position on the outermost circumferential side of the heat generating element 41.

### <Means for Improving Thermal Uniformity of Holding Surface>

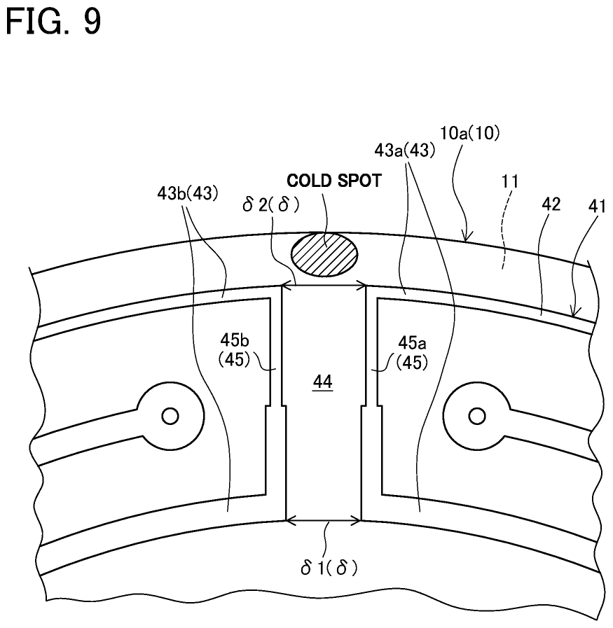

In the case where the heat generating element 41 is provided inside the upper stage part 10a of the ceramic member 10 as described above, the conventional art is configured such that an interval δ between the first folded-back portion 45a and the second folded-back portion 45b positioned on the outermost circumferential side of the heat generating element 41 is constant along a radial direction of the heat generating element 41. Alternatively, as shown in FIG. 9, an interval δ (δ2 in FIG. 9) on an outer circumferential side in the radial direction of the heat generating element 41 is larger than an interval δ (δ1 in FIG. 9) on an inner circumferential side.

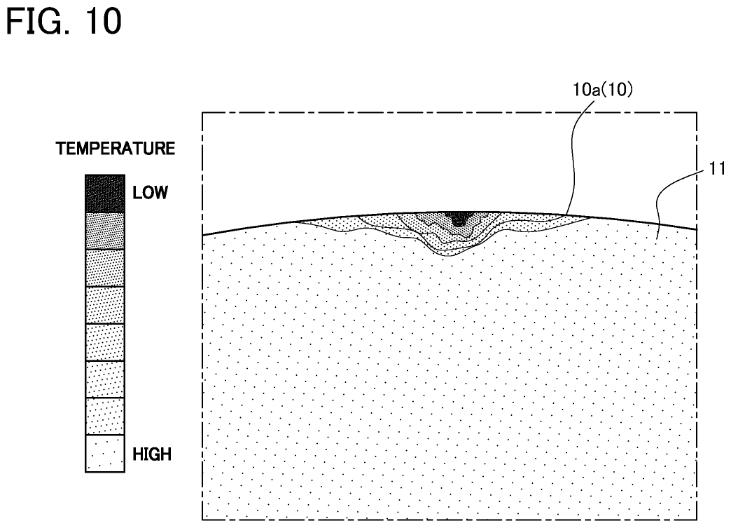

In such a conventional art, in a portion around a portion where the heat generating element 41 is not arranged (specifically, a portion on the outer circumferential side with respect to the separation region 44 (on the outer circumferential side in the radial direction; an upper side in FIG. 9)), because the heat generating lines 42 of the heat generating element 41 are respectively folded back via the pair of folded-back portions 45, temperature decreases and a cold spot (temperature singular point) is generated, so that thermal uniformity on the holding surface 11 is difficult to be maintained. As shown in FIG. 10, an evaluation result of temperature distribution in the holding surface 11 reveals that a low-temperature region was generated in a position on the outer circumferential side of the holding surface 11.

In the present embodiment, regarding the pair of folded-back portions 45 (a part a surrounded by a broken line in FIG. 4) formed in the position on the outermost circumferential side of the heat generating element 41, as shown in FIG. 4 or FIG. 5, the pair of folded-back portions 45 are formed in a truncated-chevron shape with a distance therebetween narrowing toward the outer circumferential side of the heat generating element 41. Accordingly, the interval δ between the first folded-back portion 45a and the second folded-back portion 45b (hereinafter, simply referred to as the “interval δ”) gradually narrows toward the outer circumferential side of the heat generating element 41, i.e., upward in FIG. 4 and FIG. 5.

As described above, in the present embodiment, as shown in FIG. 5, the interval δ at a position of an end 45-2 (an end on the outer circumferential side in the radial direction) on the outer circumferential side of the pair of folded-back portions 45 is narrow, compared to the interval δ at a position of an end 45-1 (an end on the inner circumferential side in the radial direction) on the inner circumferential side of the pair of folded-back portions 45.

That is, regarding the interval δ, the interval δ2 on the outer circumferential side is narrower than the interval δ1 on the inner circumferential side. The interval δ2 on the outer circumferential side is narrow while maintaining a distance enough to prevent a short circuit.

The interval δ1 on the inner circumferential side is the interval δ of the pair of folded-back portions 45 at the ends 45-1 on the inner circumferential side in the radial direction of the heat generating element 41. The interval δ2 on the outer circumferential side is the interval & of the pair of folded-back portions 45 at the ends 45-2 on the outer circumferential side in the radial direction of the heat generating element 41. The interval δ1 on the inner circumferential side and the interval δ2 on the outer circumferential side are each 0.5 mm to 5.0 mm. As an example, the interval δ1 on the inner circumferential side is 3.5 mm, and the interval δ2 on the outer circumferential side is 1.0 mm.

The ends 45-1 on the inner circumferential side and the ends 45-2 on the outer circumferential side are each one example of “an end on one side in the radial direction” of the present disclosure. Each end 45-2 on the outer circumferential side is one example of “an end on the outer circumferential side in the radial direction” of the present disclosure.

The interval δ between the pair of folded-back portions 45 gradually narrows from between the the inner-circumferential-side ends 45-1 to between the the outer-circumferential-side ends 45-2 as shown in FIG. 5.

In other words, the interval δ between the pair of folded-back portions 45 is narrow between the outer-circumferential-side ends 45-2, compared to the interval δ between middle portions 45-3 in the radial direction, as shown in FIG. 5. That is, the interval δ2 between the pair of folded-back portions 45 on the outer circumferential side is narrower than the interval δ3 between the middle portion. The interval δ3 between the middle portions is the interval δ at the middle portions 45-3 of the pair of folded-back portions 45 in the radial direction of the heat generating element 41. In addition, the middle portions 45-3 are located apart by the same distance from each of the inner-circumferential-side ends 45-1 and the outer-circumferential-side ends 45-2, i.e., one end and the other end in the radial direction of the heat generating element 41.

As described above, the interval δ between the pair of folded-back portions 45 that are located on the outermost circumferential side of the heat generating element 41 is narrower between the outer-circumferential-side ends 45-2, and thus a heat quantity can be increased around the outer-circumferential-side ends 45-2. Thus, on the outermost circumferential side of the heat generating element 41, generation of a cold spot can be prevented in a portion around the ends 45-2 on the outer circumferential side where temperature tends to decrease, that is, a portion where no heat generating element 41 is arranged because the heat generating lines 42 of the heat generating element 41 are respectively folded back via the pair of folded-back portions 45, specifically a portion on the outer circumferential side (on an upper side in FIG. 5) with respect to the separation region 44. Therefore, thermal uniformity on the holding surface 11 of the ceramic member 10 can be improved.

### <Effects of the Present Embodiment>

As described above, in the present embodiment, the interval δ between the ends of the pair of folded-back portions 45 on one side in the radial direction of the heat generating element 41, that is, the interval δ2 on the outer circumferential side, is narrower than the interval δ3 between the middle portions.

As described above, the interval δ is narrower between the ends 45-2 on the outer circumferential side, whereby the heat quantity can be increased around the ends 45-2 on the outer circumferential side. Thus, generation of a cold spot can be prevented in a portion around the ends 45-2 on the outer circumferential side where the temperature tends to decrease.

In addition, the interval δ between the middle portions 45-3 in the radial direction is wider than that between the outer-circumferential-side ends 45-2, and thus the heat quantity can be reduced around the middle portions 45-3, in the radial direction, of the pair of folded back portions 45. Therefore, generation of a hot spot can be prevented in a portion around the middle portion 45-3, in the radial direction, of the pair of folded-back portions 45 where temperature tends to increase.

The interval δ2 on the outer circumferential side of the pair of folded-back portions 45 is narrower than the interval δ1 on the inner circumferential side.

As described above, since the interval & is narrower at the position between the outer-circumferential-side ends 45-2, the heat quantity can be increased around the outer-circumferential-side ends 45-2. Thus, generation of the cold spot can be prevented in a portion around the ends 45-2 on the outer circumferential side where the temperature tends to decrease. Therefore, thermal uniformity on the holding surface 11 of the ceramic member 10 can be improved.

The interval δ gradually narrows from between the inner-circumferential-side ends 45-1 toward between the outer-circumferential-side ends 45-2.

Accordingly, the heat quantity can be increased from the position of the ends 45-1 on the inner circumferential side toward the position of the outer-circumferential-side ends 45-2 in the pair of folded-back portions 45. Thus, thermal uniformity on the holding surface 11 of the ceramic member 10 can be improved more effectively.

On the outermost circumferential side of the heat generating element 41, the pair of folded-back portions 45, that is, the pair of folded-back portions 45 having a truncated-chevron shape, are formed.

Accordingly, for the pair of folded-back portions 45 on the outermost circumferential side of the heat generating element 41, the heat quantity can be increased around the outer-circumferential-side ends 45-2, and thus generation of a cold spot can be prevented in the portion on the outer circumferential side with respect to the separation region 44 between the pair of folded-back portions 45 on the outermost circumferential side of the heat generating element 41.

In the present embodiment, such a heat generating element 41 is provided inside the upper stage part 10a of the ceramic member 10.

In an outer circumferential-side portion of the lower stage part 10b, larger than the upper stage part 10a, no heat generating element 41 is arranged, so that the temperature tends to decrease and a cold spot is easily generated. Accordingly, in the present embodiment, the interval δ is narrower between the outer-circumferential-side ends 45-2, and thus the heat quantity can be increased around the outer-circumferential-side ends 45-2. Thus, generation of the cold spot can be prevented in a portion around the ends 45-2 on the outer circumferential side where the temperature tends to decrease, that is, a portion where no heat generating element 41 is arranged because the heat generating element 41 is folded back. Therefore, thermal uniformity on the holding surface 11 of the ceramic member 10 can be improved.

If the heat generating element 41 is provided in the lower stage part 10b, there is a possibility that heat is released radially outward. However, when the heat generating element 41 is provided in the upper stage part 10a, the heat is less likely to be released to the radially outer side. Thus, the holding surface 11 can be heated more effectively. Therefore, generation of the cold spot can be prevented, and thermal uniformity can be improved.

As shown in FIG. 5, at the outer-circumferential-side ends 45-2 of the pair of folded-back portions 45, each of a corner part 46a and a corner part 46b may include an R-shaped part 47 on an inner peripheral side thereof, formed in an R shape (i.e., a circular-arc shape). Here, the corner part 46a is a portion where the end 42a, on the separation region 44 side, of the heat generating line 42 forming the first heat generating line pair 43a is connected to the first folded-back portion 45a, and that is on the outer circumferential side.

The corner part 46b is a portion where the end 42a, on the separation region 44 side, of the heat generating line 42 forming the second heat generating line pair 43b is connected with the second folded-back portion 45b, and that is on the outer circumferential side. Only one of the corner part 46a and the corner part 46b may have the R-shaped part 47 on the inner peripheral side thereof, formed in an R shape. A curvature radius R of the R-shaped part 47 is, for example, 0.05 mm to 0.3 mm, and is 0.1 mm as one example.

Accordingly, in the corner part 46a and the corner part 46b each formed in an acute-angled shape, the width of the heat generating line 42 can be increased, thereby preventing occurrence of a crack in the heat generating line 42.

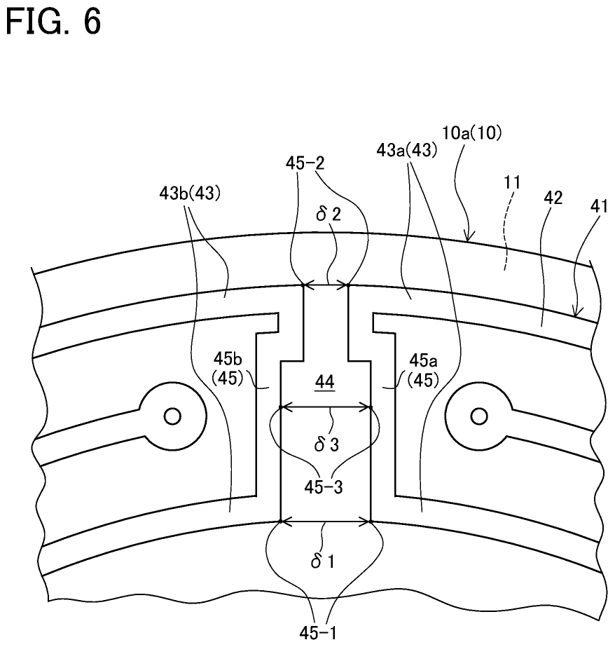

As a modification, the pair of folded-back portions 45 may be formed in a stepwise shape as shown in FIG. 6. In an example shown in FIG. 6, the first folded-back portion 45a and the second folded-back portion 45b each have a stepwise shape formed shifting toward the separation region 44, near the outer-circumferential-side ends 45-2 of the pair of folded-back portions 45.

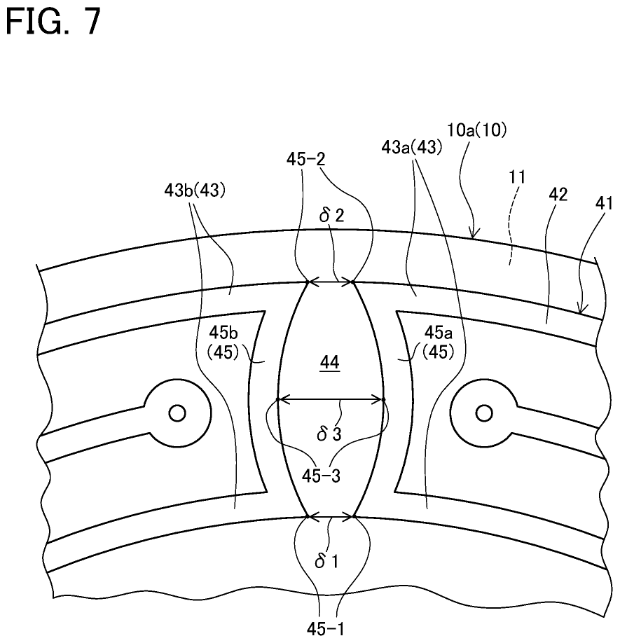

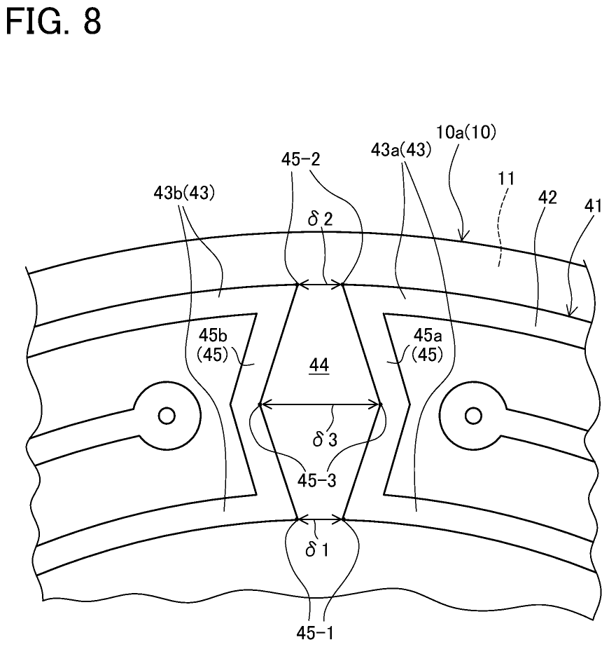

As another modification, as shown in FIG. 7 or FIG. 8, the interval & may narrow from between the middle portions 45-3 in the radial direction toward between the inner-circumferential-side ends 45-1 or the outer-circumferential-side ends 45-2 of the pair of folded-back portions 45 such that the first folded-back portion 45a and the second folded-back portion 45b are each formed in a circular-arc shape or a V shape. As described above, the interval & may be narrower between the ends on one side in the radial direction, that is, between the inner-circumferential-side ends 45-1 and the outer-circumferential-side ends 45-2, than the interval δ between the middle portions 45-3 in the radial direction.

The heat generating element 41 includes a plurality of the pairs of folded-back portions 45, arranged in positions not only on the outermost circumferential side of the heat generating element 41 but also in other positions. Here, at least one pair of folded-back portions 45 among the plurality of the pairs of folded-back portions 45 only need to be formed in a truncated-chevron shape, a stepwise shape, a circular-arc shape, or a V shape. In a position other than the position on the outermost circumferential side of the beat generating element 41, the pair of folded-back portions 45 may be formed in a truncated-chevron shape with the distance therebetween narrowing toward the inner circumferential side of the heat generating element 41, so that the interval δ may gradually narrow toward the inner circumferential side of the heat generating element 41.

The above embodiments are merely examples and are not intended to limit the present disclosure in any way, and, as a matter of course, various improvements and modifications can be made without departing from the spirit and scope of the present disclosure.

### REFERENCE SIGNS LIST

1 Electrostatic chuck
10 Ceramic member
10a Upper stage part
11 Holding surface
41 Heat generating element
42 Heat generating line
42a End of heat generating line on separation region side
43 Pair of heat generating lines
43a First heat generating line pair
43b Second beat generating line pair
44 Separation region
45 Pair of folded-back portions
45a First folded-back portion
45b Second folded-back portion
45-1 End on an inner circumferential side (of pair of folded-back portions)
45-2 End on an outer circumferential side (of pair of folded-back portions)
45-3 Middle portion (of pair of folded-back portions)

1. A ceramic heater having a plate shape, the ceramic heater comprising:
a ceramic substrate; and
a heat generating element that is embedded in the ceramic substrate and in which linear heat generating lines are arranged substantially concentrically, wherein
when seen in a thickness direction of the ceramic heater,
the heat generating element includes:
a pair of heat generating lines that are formed by two of the heat generating lines adjacent to each other in a radial direction of the heat generating element, the pair of heat generating lines including a first heat generating line pair and a second heat generating line pair that are arranged apart from each other with a predetermined separation region therebetween in a circumferential direction of the heat generating element;
a first folded-back portion that connects ends, on the separation region side, of the two heat generating lines forming the first heat generating line pair; and
a second folded-back portion that connects ends, on the separation region side, of the two heat generating lines forming the second heat generating line pair, and
a pair of folded-back portions formed by the first folded-back portion and the second folded-back portion is arranged such that:
an interval between the first folded-back portion and the second folded-back portion at ends of the pair of folded-back portions on one side in the radial direction of the heat generating element is narrower than an interval between the first folded-back portion and the second folded-back portion at middle portions of the pair of folded-back portions in the radial direction of the heat generating element.

2. The ceramic heater according to claim 1, wherein
the ends of the pair of folded-back portions, on the one side in the radial direction of the heat generating element, are ends of the pair of folded-back portions, on an outer circumferential side in the radial direction of the heat generating element, and
the interval between the first folded-back portion and the second folded-back portion at the ends of the pair of folded-back portions on the outer circumferential side in the radial direction of the heat generating element is narrower than the interval between the first folded-back portion and the second folded-back portion at ends of the pair of folded-back portions on an inner circumferential side in the radial direction of the heat generating element.

3. A ceramic heater having a plate shape, the ceramic heater comprising:
a ceramic substrate; and
a heat generating element that is embedded in the ceramic substrate and in which linear heat generating lines are arranged substantially concentrically, wherein
when seen in a thickness direction of the ceramic heater,
the heat generating element includes:
a pair of heat generating lines that are formed by two of the heat generating lines adjacent to each other in a radial direction of the heat generating element, the pair of heat generating lines including a first heat generating line pair and a second heat generating line pair that are arranged apart from each other with a predetermined separation region therebetween in a circumferential direction of the heat generating element;
a first folded-back portion that connects ends, on the separation region side, of the two heat generating lines forming the first heat generating line pair; and
a second folded-back portion that connects ends, on the separation region side, of the two heat generating lines forming the second heat generating line pair, and
a pair of folded-back portions formed by the first folded-back portion and the second folded-back portion is arranged such that:
an interval between the first folded-back portion and the second folded-back portion at ends of the pair of folded-back portions on an outer circumferential side in the radial direction of the heat generating element is narrower than an interval between the first folded-back portion and the second folded-back portion at ends of the pair of folded-back portions on an inner circumferential side in the radial direction of the heat generating element, and
the first folded-back portion and the second folded-back portion each formed toward the separation region, near the ends on the outer circumferential side, so that the interval between the first folded-back portion and the second folded-back portion is narrow near the ends on the outer circumferential side.

4. The ceramic heater according to claim 2, wherein the interval between the first folded-back portion and the second folded-back portion is narrower from between the ends on the inner circumferential side in the radial direction of the heat generating element toward between the ends on the outer circumferential side in the radial direction of the heat generating element.

5. The ceramic heater according to claim 2, wherein the pair of folded-back portions are formed in a position on an outermost circumferential side of the heat generating element.

6. The ceramic heater according to claim 1, wherein
the ceramic substrate includes:
a first portion having a holding surface for holding an object; and
a second portion that is located on a side opposite to the holding surface of the first portion in a thickness direction of the ceramic heater, and that has an outer circumference larger than that of the first portion when seen from the thickness direction of the ceramic heater, and
the heat generating element is provided in the first portion.

7. The ceramic heater according to claim 1, wherein
at the position of the ends of the pair of folded-back portions, on the one side or the outer circumferential side in the radial direction of the heat generating element,
at least one of: a corner part where the end on the separation region side of the heat generating lines forming the first heat generating line pair is connected with the first folded-back portion; and a corner part where the end on the separation region side of the heat generating lines forming the second heat generating line pair is connected with the second folded-back portion is formed in an R shape on an inner peripheral side of the corner part.

8. A holding member for holding an object, comprising the ceramic heater according to claim 1.

9. The ceramic heater according to claim 3, wherein the interval between the first folded-back portion and the second folded-back portion is narrower from between the ends on the inner circumferential side in the radial direction of the heat generating element toward between the ends on the outer circumferential side in the radial direction of the heat generating element.

10. The ceramic heater according to claim 3, wherein the pair of folded-back portions are formed in a position on an outermost circumferential side of the heat generating element.

11. The ceramic heater according to claim 3, wherein
the ceramic substrate includes:
a first portion having a holding surface for holding an object; and
a second portion that is located on a side opposite to the holding surface of the first portion in a thickness direction of the ceramic heater, and that has an outer circumference larger than that of the first portion when seen from the thickness direction of the ceramic heater, and
the heat generating element is provided in the first portion.

12. The ceramic heater according to claim 3, wherein
at the position of the ends of the pair of folded-back portions, on the one side or the outer circumferential side in the radial direction of the heat generating element,
at least one of: a corner part where the end on the separation region side of the heat generating lines forming the first heat generating line pair is connected with the first folded-back portion; and a corner part where the end on the separation region side of the heat generating lines forming the second heat generating line pair is connected with the second folded-back portion is formed in an R shape on an inner peripheral side of the corner part.

13. A holding member for holding an object, comprising the ceramic heater according to claim 3.

14. The ceramic heater according to claim 4, wherein
the pair of folded-back portions are formed in a position on an outermost circumferential side of the heat generating element.

15. The ceramic heater according to claim 4, wherein
the ceramic substrate includes:
a first portion having a holding surface for holding an object; and
a second portion that is located on a side opposite to the holding surface of the first portion in a thickness direction of the ceramic heater, and that has an outer circumference larger than that of the first portion when seen from the thickness direction of the ceramic heater, and
the heat generating element is provided in the first portion.

16. The ceramic heater according to claim 4, wherein
at the position of the ends of the pair of folded-back portions, on the one side or the outer circumferential side in the radial direction of the heat generating element,
at least one of: a corner part where the end on the separation region side of the heat generating lines forming the first heat generating line pair is connected with the first folded-back portion; and a corner part where the end on the separation region side of the heat generating lines forming the second heat generating line pair is connected with the second folded-back portion is formed in an R shape on an inner peripheral side of the corner part.

17. A holding member for holding an object, comprising the ceramic heater according to claim 4.

18. The ceramic heater according to claim 5, wherein
the ceramic substrate includes:
a first portion having a holding surface for holding an object; and
a second portion that is located on a side opposite to the holding surface of the first portion in a thickness direction of the ceramic heater, and that has an outer circumference larger than that of the first portion when seen from the thickness direction of the ceramic heater, and
the heat generating element is provided in the first portion.

19. The ceramic heater according to claim 5, wherein
at the position of the ends of the pair of folded-back portions, on the one side or the outer circumferential side in the radial direction of the heat generating element,
at least one of: a corner part where the end on the separation region side of the heat generating lines forming the first heat generating line pair is connected with the first folded-back portion; and a corner part where the end on the separation region side of the heat generating lines forming the second heat generating line pair is connected with the second folded-back portion is formed in an R shape on an inner peripheral side of the corner part.

20. A holding member for holding an object, comprising the ceramic heater according to claim 5.
